(19) United States
(12) Patent Application Publication
(10) Pub. No.: US 2025/0038040 A1
(43) Pub. Date: Jan. 30, 2025

(54) LIFT FRAMES FOR CENTRAL HEATING, AND RELATED PROCESSING CHAMBERS AND METHODS

(71) Applicant: Applied Materials, Inc., Santa Clara, CA (US)

(72) Inventors: Ala MORADIAN, Sunnyvale, CA (US); Shu-Kwan LAU, Sunnyvale, CA (US); Zuoming ZHU, Sunnyvale, CA (US)

(21) Appl. No.: 18/227,128

(22) Filed: Jul. 27, 2023

(51) Int. Cl. H01L 21/687; H01L 21/02; H01L 21/67

(52) U.S. Cl. CPC H01L 21/6875; H01L 21/0262; H01L 21/67115; H01L 21/68742; H01L 21/68757

(57) ABSTRACT

Embodiments described herein relate to lift frames for central heating, and related processing chambers and methods. In one or more embodiments, a lift frame for positioning in a processing chamber applicable for use in semiconductor manufacturing includes a shaft. The shaft includes an opening formed in the shaft, and the shaft includes a first material. The lift frame includes a plurality of arms extending outwardly relative to the shaft, and an absorptive mass disposed in the opening of the shaft. The absorptive mass includes a second material having a higher absorptivity than the first material of the shaft.

### BACKGROUND

### Field

Embodiments described herein relate to lift frames for central heating, and related processing chambers and methods.

### Description of the Related Art

Semiconductor substrates are processed for a wide variety of applications, including the fabrication of integrated devices and micro-devices. One method of processing substrates includes depositing a material, such as a dielectric material or a semiconductive material, on an upper surface of the substrate. The material may be deposited in a lateral flow chamber by flowing a process gas parallel to the surface of a substrate positioned on a support, and thermally decomposing the process gas to deposit a material from the gas onto the substrate surface. However, operations (such as epitaxial deposition operations) can be long, expensive, and inefficient, and can have limited capacity and throughput. Moreover, hardware can involve relatively large dimensions that occupy higher footprints in manufacturing facilities. Additionally, processing can involve non-uniformities (such as temperature non-uniformities), which can involve hindered device performance and/or reduced throughput.

Therefore, a need exists for improved apparatuses and methods in semiconductor processing.

### SUMMARY

Embodiments described herein relate to lift frames for central heating, and related processing chambers and methods.

In one or more embodiments, a lift frame for positioning in a processing chamber applicable for use in semiconductor manufacturing includes a shaft. The shaft includes an opening formed in the shaft, and the shaft includes a first material. The lift frame includes a plurality of arms extending outwardly relative to the shaft, and an absorptive mass disposed in the opening of the shaft. The absorptive mass includes a second material having a higher absorptivity than the first material of the shaft.

In one or more embodiments, a processing chamber applicable for use in semiconductor manufacturing includes a chamber body. The chamber body includes an internal volume, a plurality of gas inject passages formed in the chamber body, and one or more gas exhaust passages formed in the chamber body. The processing chamber includes one or more heat sources configured to generate heat, a liner disposed in the internal volume and lining at least part of one or more sidewalls of the chamber body, and a substrate support assembly positioned in the processing volume. The substrate support assembly includes a lift frame. The lift frame includes a shaft that includes an opening formed in the shaft. The shaft includes a first material. The lift frame includes a plurality of arms extending outwardly relative to the shaft. The processing chamber includes a bias heat source oriented toward the opening formed in the shaft.

In one or more embodiments, a method of processing substrates for semiconductor manufacturing includes heating a substrate positioned on a substrate support in a processing volume of a chamber. The method includes flowing one or more process gases over the substrate to form one or more layers on the substrate. The method includes directing laser light toward a target portion of a lift frame. The lift frame at least partially supports the substrate support.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional side view of a processing apparatus, according to one or more embodiments.

FIG. 2 is a schematic cross-sectional side view of the processing apparatus shown in FIG. 1, according to one or more embodiments.

FIG. 3 is a schematic partial perspective view of a first lift frame and a second lift frame, according to one or more embodiments.

FIG. 4 is a schematic partial top view of the first lift frame and the second lift frame shown in FIG. 3, according to one or more embodiments.

FIG. 5 is a schematic side cross-sectional view of the first lift frame, along Section 5-5 shown in FIG. 4, according to one or more embodiments.

FIG. 6 is a schematic partial perspective view of a first lift frame and the second lift frame, according to one or more embodiments.

FIG. 7 is a schematic side cross-sectional view of the first lift frame shown in FIG. 6, according to one or more embodiments.

FIG. 8 is a schematic block diagram view of a method of processing substrates for semiconductor manufacturing, according to one implementation.

FIG. 9 is a schematic top view of a temperature profile for the lowermost substrate shown in FIG. 1, during processing, according to one or more embodiments.

FIG. 10 is a schematic side cross-sectional view of the first lift frame shown in FIG. 7, according to one or more embodiments.

FIG. 11 is a schematic side cross-sectional view of the first lift frame shown in FIG. 10, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein relate to lift frames for central heating, and related processing chambers and methods. The lift frames described herein can be used to direct heat (e.g., light) toward central area(s) of one or more substrates being processed. The direction of heat can, for example, correct for a colder central area(s) of the one or more substrates across a variety of processing parameters (e.g., processing temperatures and/or temperature profiles). The colder central area(s) can be affected, for example, by chamber components that at least partially obstruct a direct vertical line of sight between the central area(s) and one or more heat sources.

The disclosure contemplates that terms such as “couples,” “coupling,” “couple,” and “coupled” may include but are not limited to welding, fusing, melting together, interference fitting, and/or fastening such as by using bolts, threaded connections, pins, and/or screws. The disclosure contemplates that terms such as “couples,” “coupling,” “couple,” and “coupled” may include but are not limited to integrally forming. The disclosure contemplates that terms such as “couples,” “coupling,” “couple,” and “coupled” may include but are not limited to direct coupling and/or indirect coupling, such as indirect coupling through components such as links, blocks, and/or frames.

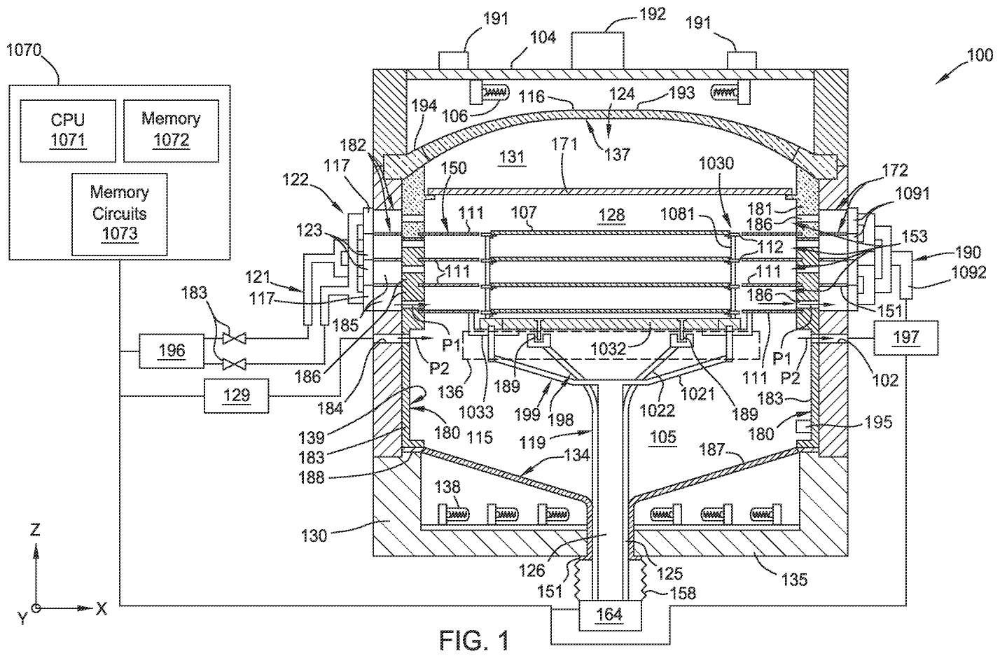

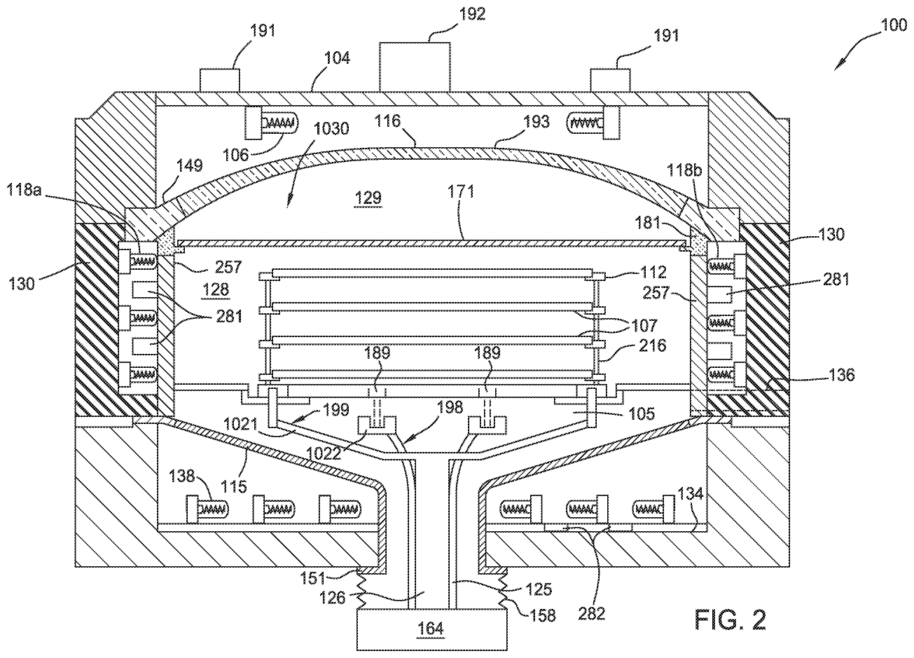

FIG. 1 is a schematic cross-sectional side view of a processing apparatus 100, according to one or more embodiments. The side heat sources 118a, 118b shown in FIG. 2 are not shown in FIG. 1 for visual clarity purposes. The processing apparatus 100 includes a processing chamber having a chamber body 130 that defines an internal volume 124. In one or more embodiments, the processing apparatus 100 includes a plate 171 disposed in the internal volume 124 and at least partially defining a processing volume 128 of the internal volume 124.

A cassette 1030 is positioned in the processing volume 128 and at least partially supported by a substrate support assembly 119 (such as a pedestal assembly). The cassette 1030 includes a cassette plate 1032 and a plurality of levels that support a plurality of substrates 107 for simultaneous processing (e.g., epitaxial deposition). The present disclosure contemplates that the cassette plate 1032 can be omitted. In the implementation shown in FIG. 1, the cassette 1030 supports four substrates. The cassette 1030 can support other numbers of substrates, including but not limited to two substrates 107, three substrates 107, four substrates 107, six substrates 107, or eight substrates 107. In one or more embodiments, the cassette 1030 supports two substrates 107 or three substrates 107. The processing apparatus 100 includes an upper window 116, such as a dome, disposed between a lid 104 and the processing volume 128.

The processing apparatus 100 includes a lower window 115 disposed below the processing volume 128. One or more upper heat sources 106 are positioned above the processing volume 128 and the upper window 116. The one or more upper heat sources 106 can be radiant heat sources such as lamps, for example halogen lamps. The one or more upper heat sources 106 are disposed between the upper window 116 and the lid 104. The upper heat sources 106 are positioned to facilitate uniform heating of the substrates 107. One or more lower heat sources 138 are positioned below the processing volume 128 and the lower window 115. The one or more lower heat sources 138 can be radiant heat sources such as lamps, for example halogen lamps. The lower heat sources 138 are disposed between the lower window 115 and a floor 134 of the internal volume 124. The lower heat sources 138 are positioned to facilitate uniform heating of the substrates 107. A bias heat source 195 is oriented toward the first lift frame 199 and/or the second lift frame 198.

The present disclosure contemplates that other heat sources may be used (in addition to or in place of the lamps) for the various heat sources described herein. For example, resistive heaters, light emitting diodes (LEDs), and/or lasers may be used for the various heat sources described herein.

The upper and lower windows 116, 115 may be transparent to the infrared radiation, such as by transmitting at least 80% (such as at least 95%) of infrared radiation. The upper and lower windows 116, 115 may be a quartz material (such as a transparent quartz). In one or more embodiments, the upper window 116 includes an inner window 193 and outer window supports 194. The inner window 193 may be a thin quartz window. The outer window supports 194 support the inner window 193 and are at least partially disposed within a support groove. In one or more embodiments, the lower window 115 includes an inner window 187 and outer window supports 188. The inner window 187 may be a thin quartz window. The outer window supports 188 support the inner window 187.

The substrate support assembly 119 is disposed in the processing volume 128. One or more liners 180 are disposed in the processing volume 128 and surround the substrate support assembly 119. The one or more liners 180 facilitate shielding the chamber body 130 from processing chemistry in the processing volume 128. The chamber body 130 is disposed at least partially between the upper window 116 and the lower window 115. The one or more liners 180 are disposed between the processing volume 128 and the chamber body 130. The one or more liners 180 include an upper liner 181 and one or more lower liners 183.

The processing apparatus 100 includes a plurality of gas inject passages 182 formed in the chamber body 130 and in fluid communication with the processing volume 128, and one or more gas exhaust passages 172 (a plurality is shown in FIG. 1) formed in the chamber body 130 opposite the plurality of gas inject passages 182. The one or more gas exhaust passages 172 are in fluid communication with the processing volume 128. Each of the plurality of gas inject passages 182 and one or more gas exhaust passages 172 are formed through one or more sidewalls of the chamber body 130 and through the one or more liners 180 that line the one or more sidewalls of the chamber body 130.

Each gas inject passage 182 includes a gas channel 185 formed in the chamber body 130 and one or more gas openings 186 (one is shown in FIG. 1) formed in the one or more liners 180. One or more supply conduit systems are in fluid communication with the gas inject passages 182. In FIG. 1, an inner supply conduit system 121 and an outer supply conduit system 122 are in fluid communication with the gas inject passages 182. The inner supply conduit system 121 includes a plurality of inner gas boxes 123 mounted to the chamber body 130 and in fluid communication with an inner set of the gas inject passages 182. The outer supply conduit system 122 includes a plurality of outer gas boxes 117 mounted to the chamber body 130 and in fluid communication with an outer set of the gas inject passages 182. The present disclosure contemplates that a variety of gas supply systems (e.g., supply conduit system(s), gas inject passages, and/or gas boxes different than what is shown in FIG. 1) may be used.

The processing apparatus 100 includes a flow guide structure 150 having one or more flow dividers 111 positioned outwardly of the cassette 1030. Four flow dividers 111 are shown in FIG. 1. Other numbers (such as two or three) of the flow dividers 111 may be used. The flow guide structure 150 divides the processing volume into a plurality of flow levels 153 (four flow levels are shown in FIG. 1). In one or more embodiments, the flow guide structure 150 includes at least two (such as at least three) flow levels 153. The plurality of gas inject passages 182 are positioned as a plurality of inject levels such that each gas inject passage 182 corresponds to one of the plurality of inject levels. Each inject level aligns with a respective flow level 153.

The flow guide structure 150, the one or more liners 180 (such as the upper liner 181 and/or the one or more lower liners 183), and/or the cassette 1030 are formed of one or more of quartz (such as transparent quartz, e.g. clear quartz; opaque quartz, e.g. white quartz, or grey quartz; and/or black quartz), silicon carbide (SiC), and/or graphite coated with SiC.

The one or more flow dividers 111 are coupled to and/or at least partially supported by the one or more liners 180. Portions (e.g., the one or more flow dividers 111) of the flow guide structure 150 may each act as a pre-heat ring for each flow level 153. The one or more flow dividers 111 can be referred to as one or more pre-heat rings.

As described below, the present disclosure contemplates that the flow guide structure 150 can be omitted.

During operations (such as during an epitaxial deposition operation), one or more process gases P1 are supplied to the processing volume 128 through the inner supply conduit system 121 and the outer supply conduit system 122, and through the plurality of gas inject passages 182. The one or more process gases P1 are supplied from one or more gas sources 196 in fluid communication with the plurality of gas inject passages 182. Each of the gas inject passages 182 is configured to direct the one or more processing gases P1 in a generally radially inward direction towards the cassette 1030. As such, in one or more embodiments, the gas inject passages 182 may be part of a cross-flow gas injector. The flow(s) of the one or more process gases P1 can be divided into the plurality of flow levels 153. In one or more embodiments, the plate 171 separates the processing volume 128 from an upper section 131 of the internal volume 124. For at least the uppermost flow level 153 (or a single flow level 153—if a single flow level 153 is used), the one or more process gases P1 can be guided (using the plate 171) along a streamlined flow path such that diversive flow away from the uppermost substrate 107 (or a single substrate 107—if a single substrate 107 is used) is reduced or eliminated.

The processing apparatus 100 includes an exhaust conduit system 190. The one or more process gases P1 can be exhausted through exhaust gas openings formed in the one or more liners 180, exhaust gas channels formed in the chamber body 130, and then through exhaust gas boxes 1091. The one or more process gases P1 can flow from exhaust gas boxes 1091 and to an optional common exhaust box 1092, and then out through a conduit using one or more pump devices 197 (such as one or more vacuum pumps).

The one or more processing gases P1 can include, for example, purge gases, cleaning gases, and/or deposition gases. The deposition gases can include, for example, one or more reactive gases carried in one or more carrier gases. The one or more reactive gases can include, for example, silicon and/or germanium containing gases (such as silane (SiH₄), disilane (Si₂H₆), dichlorosilane (SiH₂Cl₂), and/or germane (GeH₄)), chlorine containing etching gases (such as hydrogen chloride (HCl)), and/or dopant gases (such as phosphine (PH₃) and/or diborane (B₂H₆)). The one or more purge gases can include, for example, one or more of argon (Ar), helium (He), nitrogen (N₂), hydrogen chloride (HCl), and/or hydrogen (H₂).

Purge gas P2 supplied from a purge gas source 129 is introduced to a bottom region 105 of the internal volume 124 through one or more purge gas inlets 184 formed in the sidewall of the chamber body 130.

The one or more purge gas inlets 184 are disposed at an elevation below the gas inject passages 182. If the one or more liners 180 are used, a section of the one or more liners 180 may be disposed between the gas inject passages 182 and the one or more purge gas inlets 184. The one or more purge gas inlets 184 are configured to direct the purge gas P2 in a generally radially inward direction. The one or more purge gas inlets 184 may be configured to direct the purge gas P2 in an upward direction. During a film formation process, the substrate support assembly 119 is located at a position that can facilitate the purge gas P2 to flow generally along a flow path across a back side of the cassette 1030. The purge gas P2 exits the bottom region 105 and is exhausted out of the processing apparatus 100 through one or more purge gas exhaust passages 102 located on the opposite side of the processing volume 128 relative to the one or more purge gas inlets 184.

The substrate support assembly 119 includes a first lift frame 199 and a second lift frame 198 disposed at least partially about the first lift frame 199. The first lift frame 199 includes arms 1021 coupled to the cassette 1030 such that lifting and lowering the first lift frame 199 lifts and lowers the cassette 1030. A plurality of lift pins 189 are suspended from the cassette 1030. Lowering of the cassette 1030 and/or lifting of the second lift frame 198 initiates contact of the lift pins 189 with arms 1022 of the second lift frame 198. Continued lowering of the cassette 1030 and/or lifting of the second lift frame 198 initiates contact of the lift pins 189 with the substrates 107 in the cassette 1030 such that the lift pins 189 raise the substrates in the cassette 1030. A bottom region 105 of the processing apparatus 100 is defined between the floor 134 and the cassette 1030. As shown in FIG. 1, the lift pins 189 can be configured to abut against—and be lifted from—the arms 1022.

A first shaft 126 of the first lift frame 199, a second shaft 125 of the second lift frame 198, and a section 151 of the lower window 115 extend through a port formed in a bottom 135 of the chamber body 130 and the floor 134. Each shaft 125, 126 is coupled to one or more respective motors 164, which are configured to independently raise, lower, and/or rotate the cassette 1030 using the first lift frame 199, and to independently raise and lower the lift pins 189 using the second lift frame 198. The first lift frame 199 includes the first shaft 126 and a plurality of first arms 1021 configured to support the cassette 1030 that includes one or more substrate supports 112. The cassette 1030 includes a plurality of mount columns 1081 that support the arcuate supports 112.

The second lift frame 198 includes the second shaft 125 and the plurality of second arms 1022 configured to interface with and support the lift pins 189. A bellows assembly 158 circumscribes and encloses a portion of the shafts 125, 126 disposed outside the chamber body 130 to facilitate reduced or eliminated vacuum leakage outside the chamber body 130.

An opening 136 (a substrate transfer opening) is formed through the one or more sidewalls of the chamber body 130. The opening 136 may be used to transfer the substrates 107 to or from the cassette 1030, e.g., in and out of the internal volume 124. In one or more embodiments, the opening 136 includes a slit valve. In one or more embodiments, the opening 136 may be connected to any suitable valve that enables the passage of substrates therethrough. The opening 136 is shown in ghost in FIGS. 1 and 2 for visual clarity purposes.

The processing apparatus 100 may include one or more sensors 191, 192, 282, such as temperature sensors (e.g., optical pyrometers) or other metrology sensors, which measure temperatures (or other parameters) within the processing apparatus 100 (such as on the surfaces of the upper window 116, surfaces of the plate assembly 300, and/or one or more surfaces of the substrates 107, the flow guide structure 150, and/or the cassette 1030). The one or more sensors 191, 192 are disposed on the lid 104. The one or more sensors 282 (e.g., lower pyrometers)—which are shown in FIG. 2—are disposed on a lower side of the lower window 115. The one or more sensors 282 can be disposed adjacent to and/or on the bottom 135 of the chamber body 130.

In one or more embodiments, upper sensors 191, 192 are oriented toward a top of the cassette 1030, the plate 171, and/or a top of the flow guide structure 150. In one or more embodiments, side sensors 281 (e.g., side temperature sensors) are oriented toward substrate supports 112 of the cassette 1030. In one or more embodiments, lower sensors 282 are oriented toward a bottom of the cassette 1030 (such as a lower surface of the cassette plate 1032), a bottom of the plate 171, and/or a bottom of the flow guide structure 150.

The processing apparatus 100 includes a controller 1070 configured to control the processing apparatus 100 or components thereof. For example, the controller 1070 may control the operation of components of the processing apparatus 100 using a direct control of the components or by controlling controllers associated with the components. In operation, the controller 1070 enables data collection and feedback from the respective chambers to coordinate and control performance of the processing apparatus 100.

The controller 1070 generally includes a central processing unit (CPU) 1071, a memory 1072, and support circuits 1073. The CPU 1071 may be one of any form of a general purpose processor that can be used in an industrial setting. The memory 1072, or non-transitory computer readable medium, is accessible by the CPU 1071 and may be one or more of memory such as random access memory (RAM), read only memory (ROM), floppy disk, hard disk, or any other form of digital storage, local or remote. The support circuits 1073 are coupled to the CPU 1071 and may include cache, clock circuits, input/output subsystems, power supplies, and the like.

The various methods (such as the method 800) and operations disclosed herein may generally be implemented under the control of the CPU 1071 by the CPU 1071 executing computer instruction code stored in the memory 1072 (or in memory of a particular processing chamber) as, e.g., a software routine. When the computer instruction code is executed by the CPU 1071, the CPU 1071 controls the components of the processing apparatus 100 to conduct operations in accordance with the various methods and operations described herein. In one embodiment, which can be combined with other embodiments, the memory 1072 (a non-transitory computer readable medium) includes instructions stored therein that, when executed, cause the methods (such as the method 800) and operations (such as the operations 802-808) described herein to be conducted. The controller 1070 can be in communication with the heat sources, the gas sources, and/or the vacuum pump(s) of the processing apparatus 100, for example, to cause a plurality of operations to be conducted.

FIG. 2 is a schematic cross-sectional side view of the processing apparatus 100 shown in FIG. 1, according to one or more embodiments. The cross-sectional view shown in FIG. 2 is rotated by 55 degrees relative to the cross-sectional view shown in FIG. 1.

The processing apparatus 100 includes one or more side heat sources 118a, 118b (e.g., side lamps, side resistive heaters, side LEDs, and/or side lasers, for example) positioned outwardly of the processing volume 128. One or more second side heat sources 118b are opposite one or more first side heat sources 118a across the processing volume 128.

In FIG. 2, the flow guide structure 150 is not shown for visual clarity purposes. Additionally, the present disclosure contemplates that the flow guide structure 150 can be omitted from the processing apparatus 100 shown in FIGS. 1-2. In such an implementation, the one or more process gases P1 flow into an outer annulus of the processing volume 128 from the gas inject passages 182, and then flow into openings 216 between and outwardly of the substrate supports 112 (e.g., arcuate supports) of the cassette 1030, and then into gaps between the substrates 107. The one or more process gases P1 flow out of the gaps, into the openings 216 (between and outwardly of the substrate supports 112) on an exhaust side of the substrates 107, into the outer annulus of the processing volume 128, and into the one or more gas exhaust passages 172. The present disclosure also contemplates that a plurality of lines (such as conduits) in the processing volume 128 can connect each of the gas inject passages 182 to each of the inlet openings of the cassette 1030.

In addition to the one or more sensors 191, 192 positioned above the processing volume 128 and above the second shield plate 1062, the processing apparatus 100 may include one or more sensors 281, such as temperature sensors (e.g., optical pyrometers) or other metrology sensors, which measure temperatures (or other parameters) within the processing apparatus 100 (such as on the surfaces of the upper window 116, on surface(s) of the plate 171, and/or one or more surfaces of the substrates 107, a plurality of windows 257, and/or the cassette 1030). The plurality of windows 257—if used—can be disposed in gaps between or formed in the one or more liners 180 (such as the upper liner 181 and/or the one or more lower liners 183). The one or more sensors 281 are side sensors (e.g., side pyrometers) that are positioned outwardly of the processing volume 128, outwardly of the flow guide structure 150, and outwardly of the plurality of windows 257. The one or more sensors 281 can be radially aligned, for example, with the plurality of windows 257 (as shown in FIG. 2).

The one or more side sensors 281 (such as one or more pyrometers) can be used to measure temperatures within the processing volume 128 from respective sides of the processing volume 128. The side sensors 281 are arranged in a plurality of sensor levels (three sensor levels are shown in FIG. 2). In one or more embodiments, the number of sensor levels is equal to the number of heat source levels. Each side sensor 281 can be oriented horizontally or can be directed (e.g., oriented downwardly at an angle) toward the substrate 107 and the substrate support 112 of a respective level of the cassette 1030.

The present disclosure contemplates that the side heat sources 118a, 118b, the windows 257, and/or the side sensors 281 can be omitted.

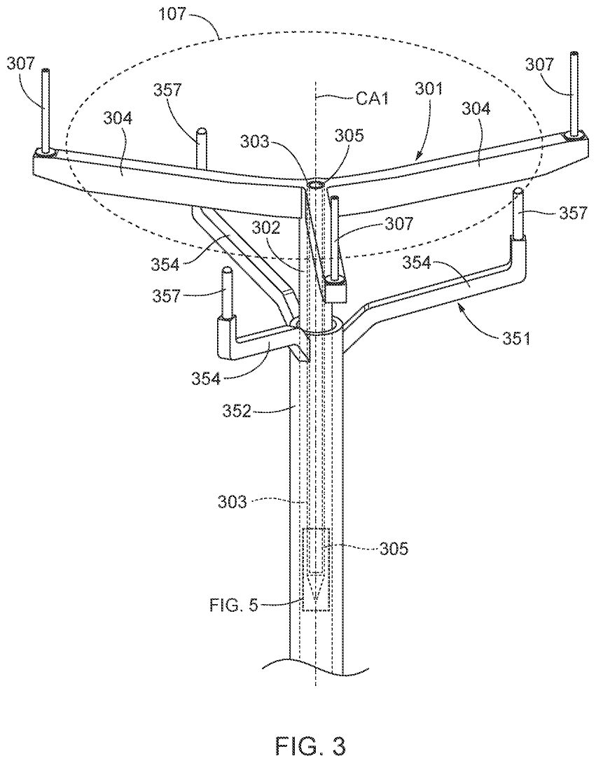

FIG. 3 is a schematic partial perspective view of a first lift frame 301 and a second lift frame 351, according to one or more embodiments. The present disclosure contemplates that the first lift frame 301 can be used at least partially as the first lift frame 199 shown in FIGS. 1 and 2, and/or the second lift frame 351 can be used at least partially as the second lift frame 198 shown in FIGS. 1 and 2.

The first lift frame 301 includes a shaft 302, and the shaft 302 includes an opening 303 formed in the shaft 302 such that the shaft 302 is partially hollow. The opening 303 is aligned or overlapped with a centerline axis CA1 of the shaft 302. The shaft 302 includes a first material. The first lift frame 301 includes a plurality of arms 304 (three are shown) extending outwardly relative to the shaft 302. In one or more embodiments, the first lift frame 301 includes an absorptive mass 305 disposed in the opening 303 of the shaft 302. The absorptive mass 305 includes a second material having a higher absorptivity than the first material of the shaft 302. In one or more embodiments, the absorptive mass 305 is formed of the second material. In one or more embodiments, the absorptive mass 305 is a rod, such as a cylindrical rod. Other shapes and sizes are contemplated for the absorptive mass 305. The first lift frame 301 includes a plurality of columns 307 (three are shown) extending (e.g. upwardly) relative to the plurality of arms 304. The columns 307 can be used as the columns 1081 shown in FIGS. 1 and 2. For example, the columns 307 can extend through the arcuate supports 112. In one or more embodiments, one or more substrate supports (such as the arcuate supports 112) are supported at least partially by the columns 307. In one or more embodiments, the shaft 302, the arms 304, and/or the columns 307 are integrally formed as a monolithic body. The present disclosure contemplates that the shaft 302, the arms 304, and/or the columns 307 can be separately formed and/or coupled together. In one or more embodiments, the shaft 302, the arms 304, and/or the columns 307 are formed of the first material.

In one or more embodiments, the first material includes a transparent quartz (e.g., SiO₂). In one or more embodiments, the first material is transmissive for at least 80% (such as at least 95%) of energy (e.g., light) having a wavelength in the infrared range.

In one or more embodiments, the second material includes one or more of silicon carbide (SiC), black quartz, opaque quartz, and/or graphite. The first material has a first emissivity that is 0.50 or less at 1,000 degrees Celsius. In one or more embodiments, the first emissivity is within a range of 0.1 to 0.5 at 1,000 degrees Celsius. The second material has a second emissivity that is larger than the first emissivity. The second emissivity is equal to or greater than 0.75 (such as 0.8 or higher, for example 0.9 or higher) at 1,000 degrees Celsius.

The second lift frame 351 includes a second shaft 352 disposed about the shaft 302. The second shaft 352 includes the first material of the shaft 302. The second lift frame 351 includes a plurality of second arms 354 extending outwardly relative to the second shaft 352. A plurality of lift pins 357 are configured to interface with the second arms 354. The lift pins 357 can be used in place of the lift pins 189 shown in FIGS. 1 and 2. In one or more embodiments the lift pins 357 are coupled to (e.g., fused to, welded to, or integrally formed with) the second arms 354. The lift pins 357 can be movable relative to second arms 354 to abut against second arms 354 and be lifted from the second arms 354.

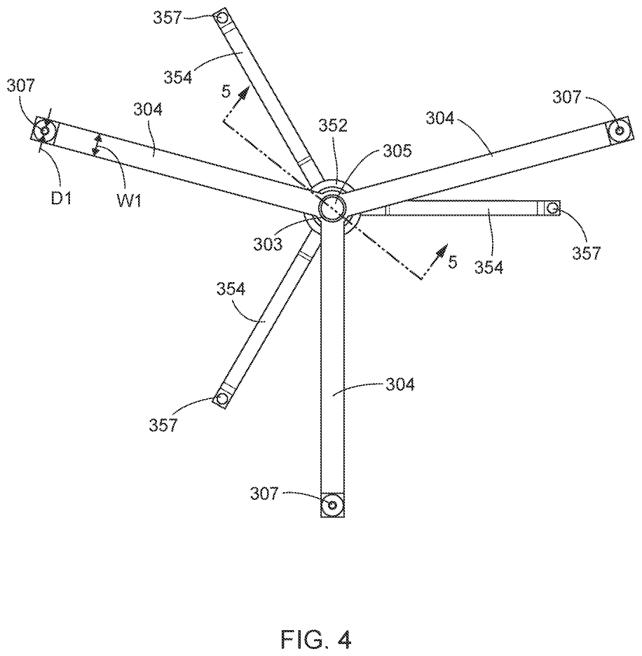

FIG. 4 is a schematic partial top view of the first lift frame 301 and the second lift frame 351 shown in FIG. 3, according to one or more embodiments.

The plurality of arms 304 have a width W1, and the plurality of columns 307 have a diameter D1 that is less than the width W1.

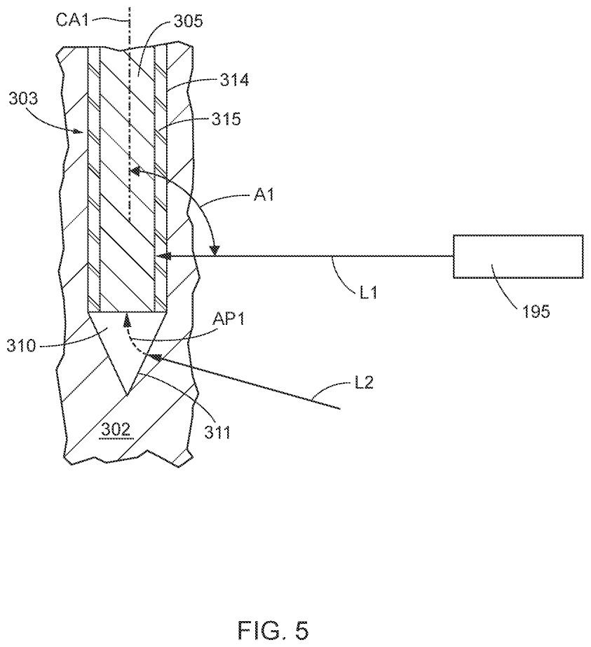

FIG. 5 is a schematic side cross-sectional view of the first lift frame 301, along Section 5-5 shown in FIG. 4, according to one or more embodiments.

The bias heat source 195 is oriented toward the absorptive mass 305 and/or the opening 303 formed in the shaft 302 to direct light L1 thereto. The bias heat source 195 is oriented at an angle A1 relative to the centerline axis CA1 of the shaft 302, and the angle A1 is less than 180 degrees, such as about 90 degrees.

The first lift frame 301 includes a beam collector 310 positioned in the opening 303 of the shaft 302. In one or more embodiments, the beam collector 310 is cone-shaped. The beam collector 310 is oriented to direct light L2 along an angled path AP1 toward the absorptive mass 305. The beam collector 310 can collected light L2 emitted by the one or more lower heat sources 138. The beam collector 310 can collect light L1 emitted by the bias heat sources 195. The beam collector 310 can be, for example, a mirror (such as a dichroic mirror) or a prism. The beam collector 310 can be a beam splitter that splits light having different wavelengths. The beam collector 310 can be at least partially integrally formed with the shaft 302. For example, the opening 303 can define one or more angled inner surfaces 311 that are part of the beam collector 310.

The first lift frame 301 includes a reflective material 315 disposed in the opening 303. In one or more embodiments, the reflective material 315 is coated onto one or more inner surfaces 314 of the shaft 302. In one or more embodiments, the reflective material 315 is integrally formed with the shaft 302. The reflective material 315 has a higher reflectivity than the shaft 302 and the absorptive mass 305. In one or more embodiments, the reflective material 315 includes one or more metals, such as gold and/or aluminum. In one or more embodiments, the reflective material 315 includes quartz. In one or more embodiments, the reflective material 315 includes a polished inner surface having an average surface roughness (Ra) that is less than 100 micro-inches, such as less than 20 micro-inches. In one or more embodiments, the reflective material 315 has a reflectivity that is at least 0.8 for light having a wavelength in the infrared (IR) range. The present disclosure contemplates that the reflective material 315 can be omitted.

In one or more embodiments, the first lift frame 301 is used as the first lift frame 199 shown in FIGS. 1 and 2, the second lift frame 351 is used as the second lift frame 198, the upper and lower heat sources 106, 138 include a plurality of lamps, and the bias heat source 195 includes a laser source.

The light L1 and/or the light L2 is absorbed by the absorptive mass 305, and is emitted from the absorptive mass 305 upwardly toward a central region of one or more of the substrates 107 to heat the central region. The reflective material 315 can reflect light back toward the absorptive mass 305.

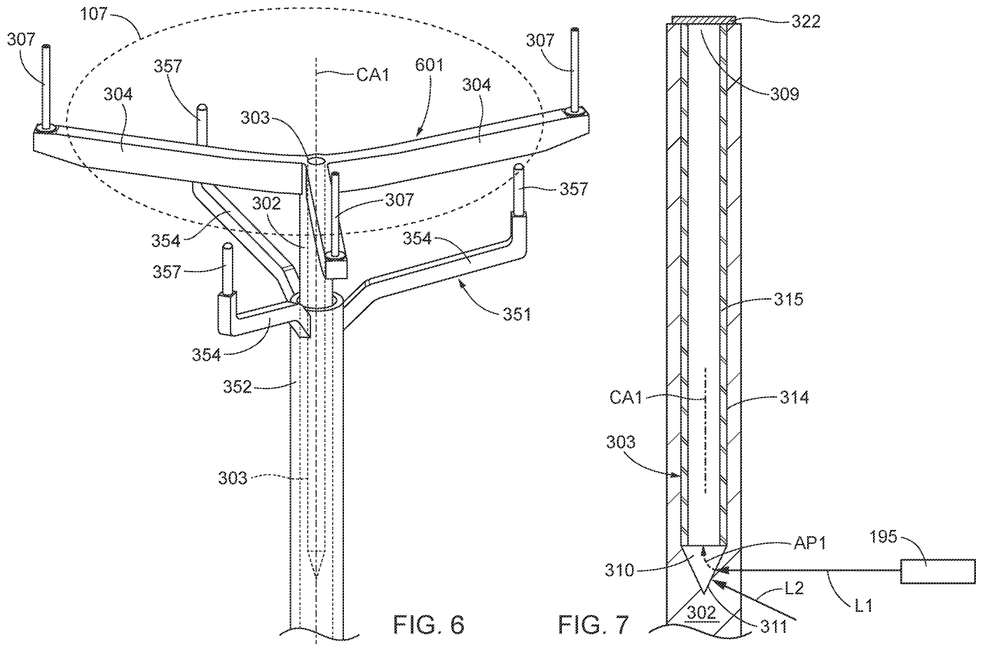

FIG. 6 is a schematic partial perspective view of a first lift frame 601 and the second lift frame 351, according to one or more embodiments. The first lift frame 601 is similar to the first lift frame 301 shown in FIG. 3.

In the implementation shown, the absorptive mass 305 is omitted.

FIG. 7 is a schematic side cross-sectional view of the first lift frame 601 shown in FIG. 6, according to one or more embodiments.

The beam collector 310 is oriented to direct light (such as light L1 and/or light L2) along the angled path AP1 and toward a top 309 of the opening 303. A size (e.g., a diameter) of the opening 303 can be used to determine a spot size of the light L1 and/or the light L2 irradiating on the lowermost substrate 107.

The first lift frame 601 includes a seal cap 322 coupled to the shaft 302 and sealing the opening 303. In one or more embodiments, the seal cap 322 is disc-shaped. The seal cap 322 can include a material (such as the first material described for the first lift frame 301 (such as the shaft 302) or the second material described for the absorptive mass 305). In one or more embodiments, the material of the seal cap 322 includes transparent quartz. In one or more embodiments, the seal cap 322 is transmissive for at least 80% (such as at least 95%) of energy (e.g., light) having a wavelength in the infrared range.

In one or more embodiments, the material of the seal cap 322 includes one or more of silicon carbide (SiC), black quartz, opaque quartz, and/or graphite. In one or more embodiments, the seal cap 322 has the second emissivity that is equal to or greater than 0.75 (such as 0.8 or greater, for example 0.9 or greater) at 1,000 degrees Celsius.

The light L1 and/or the light L2 is transmitted through the opening 303, through the seal cap 322, and upwardly toward the central region of one or more of the substrates 107 to heat the central region of the one or more substrates 107. The reflective material 315 can reflect light upwardly through the opening 303 and toward the central region of the one or more substrates 107. In one or more embodiments, the light L1 and/or the light L2 have a wavelength in the infrared range. In one or more embodiments, the light L1 has a wavelength of about 500 microns. In one or more embodiments, the one or more upper heat sources 106, the one or more lower heat sources 138, and/or the bias heat source 195 have a peak in the infrared range.

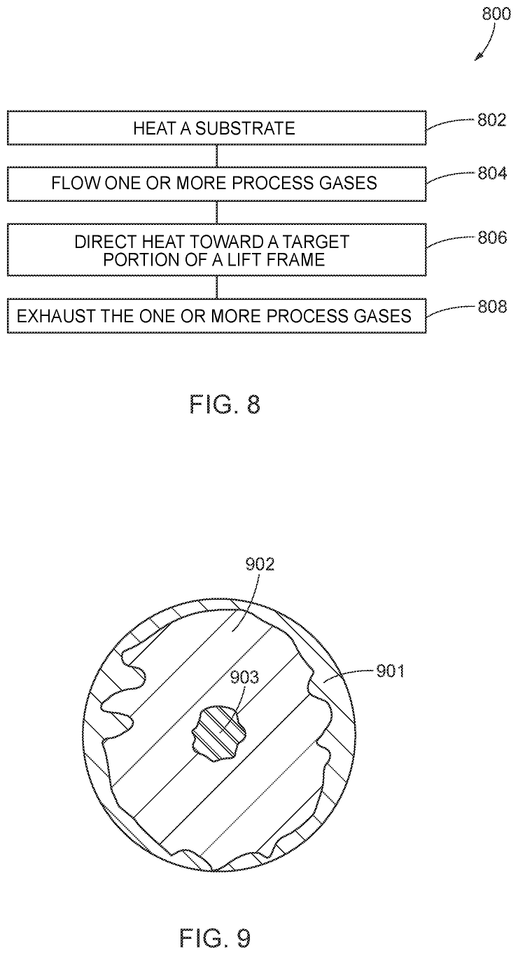

FIG. 8 is a schematic block diagram view of a method 800 of processing substrates for semiconductor manufacturing, according to one implementation.

Operation 802 includes heating a substrate positioned on a substrate support in a processing volume of a chamber. One or more additional substrates can be positioned on one or more additional substrate supports for processing.

Operation 804 includes flowing one or more process gases over the substrate to form one or more layers on the substrate.

Operation 806 includes directing heat (e.g., laser light) toward a target portion of a lift frame, the lift frame at least partially supporting the substrate support. The directing of the laser light can, for example, heat part of the lift frame (such as an absorptive mass disposed in the lift frame and/or heat a central region of one or more substrates. The lift frame can be, for example, the lift frame 301 shown in FIG. 3 or the lift frame 601 shown in FIG. 6. In one or more embodiments, the target portion is at least part of the absorptive mass. In one or more embodiments, the target portion is at least part of the shaft. In one or more embodiments, the target portion is at least part of a beam collector. Operation 806 can be conducted during operation 802 and/or operation 804.

Operation 808 includes exhausting the one or more process gases from the processing volume. During the flowing of operation 804 and/or the exhausting of operation 808, the one or more process gases can follow the flow paths described herein (such as the flow paths described in relation to FIGS. 1 and 2).

FIG. 9 is a schematic top view of a temperature profile 900 for the lowermost substrate 107 shown in FIG. 1, during processing, according to one or more embodiments.

The temperature profile 900 includes an outer region 901, a middle region 902, and a central region 901. The regions 901, 902, 903 have differing temperatures. Using subject matter described herein (such as the first lift frame 301 or the first lift frame 601), the central region 903 can be heated during a deposition operation to reduce or eliminate a temperature differential between the central region 903 and the other regions 901, 902. The reduction or elimination of the temperature differential facilitates a more uniform thickness of film deposition.

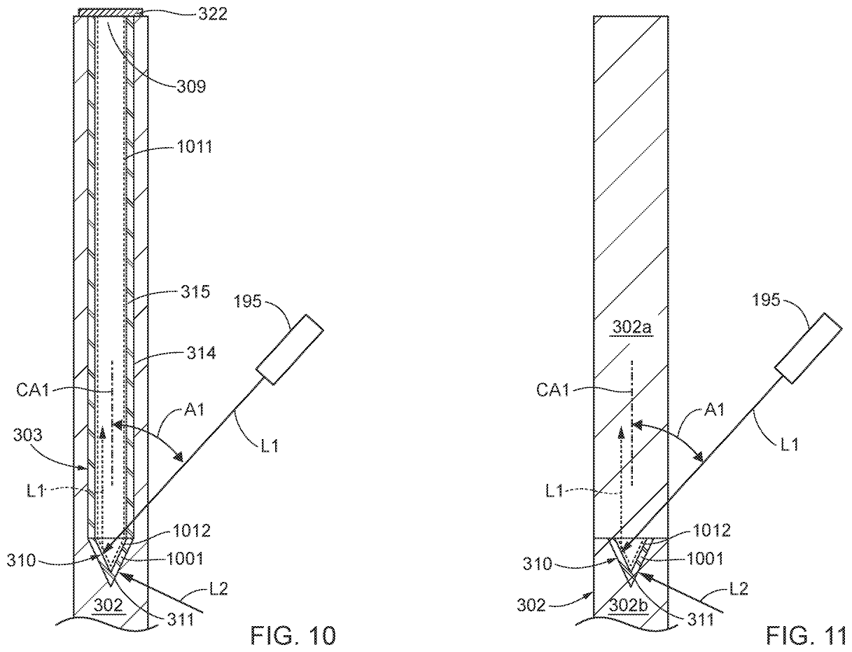

FIG. 10 is a schematic side cross-sectional view of the first lift frame 601 shown in FIG. 7, according to one or more embodiments. In the implementation shown in FIG. 10, the bias heat source 195 is oriented such that the angle A1 is less than 90 degrees.

The beam collector 310 is part of the opening 303 such that the one or more angled inner surfaces 311 are integrally formed with the shaft 302. One or more reflective sections 1001 of reflective material can be part of or disposed on the one or more angled inner surfaces 311. The reflective material of the one or more reflective sections 1001 can be the same as the material described for the reflective material 315. A transparent material 1011, 1012 can be coated over the reflective material 315 and/or the one or more reflective sections 1001 to encapsulate the reflective material 315 and/or the one or more reflective sections 1001. The transparent material 1011, 1012 can facilitate protecting the reflective material 315 and/or the one or more reflective sections 1001 from process gases. The transparent material 1011, 1012 can be the same as the first material (e.g., transparent quartz, such as SiO₂) described for the shaft 302. The seal cap 322 can be omitted. The present disclosure contemplates that the reflective material 315 can be omitted and the one or more reflective sections 1001 can be included. The light L1 transmits through the shaft 302 and reflects off of the one or more reflective sections 1001 to be columnated and directed upwardly toward the seal cap 322 (if used) and/or the lowermost substrate 107.

FIG. 11 is a schematic side cross-sectional view of the first lift frame 601 shown in FIG. 10, according to one or more embodiments.

In the implementation shown in FIG. 11, the shaft 302 includes two segments 302a, 302b that are coupled (e.g., fused) together. The opening 303 is not included for an upper segment 302a. In one or more embodiments, the beam collector 310 is part of a recess formed in a lower segment 302b. The two segments 302a, 302b are coupled together to embed the beam collector 310 in the shaft 310. In one or more embodiments, the seal cap 322, the reflective material 315, and the transparent material 1011 can be omitted. The transparent material 1012 can be omitted from the implementation shown in FIG. 11.

Benefits of the present disclosure include differentially heating central regions (e.g., colder regions) of substrates; reducing temperature non-uniformities and film thickness non-uniformities; increased throughput; enhanced device performance; thermal control and adjustability for a zones; and quick and efficient heating of zones. As an example, the lift frames described herein facilitate thermal control and adjustability for one or more zones (such as central region(s) of substrate(s)).

Such benefits can be facilitated for processing a single substrate at a time, and/or batch processing a plurality of substrates simultaneously.

It is contemplated that one or more aspects disclosed herein may be combined. As an example, one or more aspects, features, components, operations, and/or properties of the various implementations of the processing apparatus 100, the bias heat source 195, the controller 1070, the first lift frame 301, the shaft 302, the two segments 302a, 302b, the absorptive mass 305, the beam collector 310, the reflective material 315, the seal cap 322, the second lift frame 351, the first lift frame 601, the method 800, the one or more reflective sections 1001, the transparent material 1011, and/or the transparent material 1012 may be combined. Moreover, it is contemplated that one or more aspects disclosed herein may include some or all of the aforementioned benefits. As an example, the seal cap 322 may be used as part of the first lift frame 301.

While the foregoing is directed to embodiments of the present disclosure, other and further embodiments of the disclosure may be devised without departing from the basic scope thereof, and the scope thereof is determined by the claims that follow.

1. A lift frame for positioning in a processing chamber applicable for use in semiconductor manufacturing, comprising:
a shaft comprising an opening formed in the shaft, the shaft comprising a first material;
a plurality of arms extending outwardly relative to the shaft; and
an absorptive mass disposed in the opening of the shaft, the absorptive mass comprising a second material having a higher absorptivity than the first material of the shaft.

2. The lift frame of claim 1, further comprising a plurality of columns extending relative to the plurality of arms.

3. The lift frame of claim 2, wherein:
the shaft, the plurality of arms, and the plurality of columns are integrally formed as a monolithic body; and
the plurality of arms have a width, and the plurality of columns have a diameter that is less than the width.

4. The lift frame of claim 1, wherein the first material includes a transparent quartz and the second material includes one or more of silicon carbide (SiC), black quartz, opaque quartz, or graphite.

5. The lift frame of claim 1, further comprising a beam collector positioned in the opening of the shaft, the beam collector oriented to direct light along an angled path toward the absorptive mass.

6. The lift frame of claim 1, wherein the opening is aligned or overlapped with a centerline axis of the shaft.

7. The lift frame of claim 1, further comprising a reflective material disposed in the opening, wherein the reflective material has a higher reflectivity than the shaft and the absorptive mass.

8. The lift frame of claim 1, wherein:
the first material has a first emissivity that is 0.50 or less at 1,000 degrees Celsius; and
the second material has a second emissivity that is equal to or greater than 0.75 at 1,000 degrees Celsius.

9. A processing chamber applicable for use in semiconductor manufacturing, comprising:
a chamber body comprising:
an internal volume,
a plurality of gas inject passages formed in the chamber body, and
one or more gas exhaust passages formed in the chamber body;
one or more heat sources configured to generate heat;
a liner disposed in the internal volume and lining at least part of one or more sidewalls of the chamber body;
a substrate support assembly positioned in the internal volume, the substrate support assembly comprising a lift frame, the lift frame comprising:
a shaft comprising an opening formed in the shaft, the shaft comprising a first material, and
a plurality of arms extending outwardly relative to the shaft; and
a bias heat source oriented toward the opening formed in the shaft.

10. The processing chamber of claim 9, wherein the shaft comprises a first material, the bias heat source is oriented at an angle relative to a centerline axis of the shaft, and the angle is less than 180 degrees.

11. The processing chamber of claim 9, wherein the lift frame further comprises:
an absorptive mass disposed in the opening of the shaft, the absorptive mass comprising a second material having a higher absorptivity than the first material of the shaft.

12. The processing chamber of claim 9, wherein the lift frame further comprises a plurality of columns extending relative to the plurality of arms and the substrate support assembly further comprises one or more substrate supports supported at least partially by the plurality of columns.

13. The processing chamber of claim 12, wherein the substrate support assembly further comprises a plurality of lift pins and a second lift frame, the second lift frame comprising:
a second shaft disposed about the shaft, the second shaft comprising the first material; and
a plurality of second arms extending outwardly relative to the second shaft, wherein the plurality of lift pins are configured to interface with the plurality of second arms.

14. The processing chamber of claim 12, wherein the one or more heat sources comprise a plurality of lamps, and the bias heat source comprises a laser source.

15. The processing chamber claim 9, wherein the lift frame further comprises:
a reflective material disposed in the opening, wherein the reflective material has a higher reflectivity than the shaft; and
a beam collector positioned in the opening of the shaft, the beam collector oriented to direct light along an angled path toward a top of the opening.

16. The processing chamber of claim 15, wherein the lift frame further comprises a seal cap coupled to the shaft and sealing the opening, the seal cap comprising the second material.

17. A method of processing substrates for semiconductor manufacturing, the method comprising:
heating a substrate positioned on a substrate support in a processing volume of a chamber;
flowing one or more process gases over the substrate to form one or more layers on the substrate; and
directing laser light toward a target portion of a lift frame, the lift frame at least partially supporting the substrate support.

18. The method of claim 17, wherein the lift frame comprises:
a shaft comprising an opening formed in the shaft, the shaft comprising a first material; and
a plurality of arms extending outwardly relative to the shaft.

19. The method of claim 18, wherein the lift frame further comprises:
an absorptive mass disposed in the opening of the shaft, the absorptive mass comprising a second material having a higher absorptivity than the first material of the shaft, wherein the target portion is at least part of the absorptive mass.

20. The method of claim 18, wherein the lift frame further comprises:
a reflective material disposed in the opening, wherein the reflective material has a higher reflectivity than the shaft; and
a beam collector positioned in the opening of the shaft, the beam collector oriented to direct light along an angled path toward a top of the opening.
